(19) United States
(12) Patent Application Publication
(10) Pub. No.: US 2009/0014066 A1
(43) Pub. Date: Jan. 15, 2009

(54) Thin-Film Photoelectric Converter

(75) Inventors: Takashi Suezaki, Moriyama-shi (JP); Kenji Yamamoto, Kobe-shi (JP)

Correspondence Address: HOGAN & HARTSON L.L.P., 1999 AVENUE OF THE STARS, SUITE 1400, LOS ANGELES, CA, 90067, US

(73) Assignee: KANEKA CORPORATION, Osaka-shi, Osaka (JP)

(21) Appl. No.: 11/571,803

(22) PCT Filed: Jun. 23, 2005
(86) PCT No.: PCT/JP05/11497

§ 371 Date: Jan. 8, 2007

(30) Foreign Application Priority Data
Jul. 13, 2004 (JP) 2004-205852

(51) Int. Cl. H01L 31/0264; H01L 31/04

(52) U.S. Cl. 136/258; 136/261; 257/E31.004

(57) ABSTRACT

The present invention provides a three-junction thin-film photoelectric converter having high conversion efficiency at low cost by improving the film quality of the crystalline silicon photoelectric conversion layer and improving the light trapping effect.

A thin-film photoelectric converter according to the present invention is a three-junction thin-film photoelectric converter and has a structure in which a first amorphous silicon photoelectric conversion unit, a second amorphous silicon photoelectric conversion unit, a reflective intermediate layer, and a crystalline silicon photoelectric conversion unit are stacked in that order from the light incident side, wherein the photoelectric conversion units are disposed on a transparent base having surface unevenness, and the reflective intermediate layer has an unevenness depth that is smaller than that of the base.

### TECHNICAL FIELD

The present invention relates to thin-film photoelectric converters, and more particularly, to a three-junction thin-film photoelectric converter.

### BACKGROUND ART

Nowadays, various types of thin-film photoelectric converter have become available. In addition to conventional amorphous silicon-based photoelectric converters including amorphous silicon-based photoelectric conversion units, crystalline silicon-based photoelectric converters including crystalline silicon-based photoelectric conversion units have been developed, and multi-junction thin-film photoelectric converters in which such units are stacked have also been put into practical use. Herein, the term “crystalline” includes both “polycrystalline” and “microcrystalline”. The terms “crystalline” and “microcrystalline” are also used for a state partially including amorphous regions.

In general, a thin-film photoelectric converter includes a transparent electrode layer, at least one thin-film photoelectric conversion unit, and a back electrode layer stacked in that order on a transparent substrate. Furthermore, one thin-film photoelectric conversion unit includes an i-type layer sandwiched between a p-type layer and an n-type layer.

The i-type layer, which occupies a major portion of thickness of the thin-film photoelectric conversion unit, is a substantially intrinsic semiconductor layer. Since photoelectric conversion occurs mainly in the i-type layer, the i-type layer is referred as “a photoelectric conversion layer”. In order to increase light absorption and photoelectric current, a larger thickness of the i-type layer is preferable.

On the other hand, the p-type layer and the n-type layer are referred to as “conductivity-type layers” and serve to produce a diffusion potential within the thin-film photoelectric conversion unit. The value of open-circuit voltage (Voc), which is one of the characteristics of the thin-film photoelectric converter, depends on the magnitude of the diffusion potential. However, these conductivity-type layers are inactive layers that do not directly contribute to photoelectric conversion. Light absorbed by impurities doped in the conductivity-type layers does not contribute to power generation and becomes lost. Furthermore, as the conductivities of the conductivity-type layers decrease, the series resistance increases, resulting in a degradation in photoelectric conversion characteristics of the thin-film photoelectric converter. Consequently, the p-type and n-type layers preferably have the smallest possible thicknesses and high conductivities as long as they are capable of producing a sufficient diffusion potential.

For the reasons described above, the thin-film photoelectric conversion unit or the thin-film photoelectric converter is referred to as an amorphous silicon-based photoelectric conversion unit or an amorphous silicon-based thin-film photoelectric converter when the i-type layer occupying the major portion thereof is composed of an amorphous silicon-based material, and is referred to as a crystalline silicon-based photoelectric conversion unit or a crystalline silicon-based photoelectric converter when the i-type layer is composed of a crystalline silicon-based material, regardless of whether the materials of the conductivity-type layers thereof are amorphous or crystalline.

In order to improve the conversion efficiency of the thin-film photoelectric converter, a method is known in which two or more thin-film photoelectric conversion units are stacked to produce a multi-junction photoelectric converter. In this method, a front unit including a photoelectric conversion layer having a wider energy band gap is disposed closer to the light incident side of the thin-film photoelectric converter, and behind the front unit, a rear unit including a photoelectric conversion layer (e.g., composed of a Si—Ge alloy) having a narrower band gap is disposed, thereby enabling photoelectric conversion over a wide wavelength range of incident light to improve the conversion efficiency of the entire thin-film photoelectric converter.

For example, in a two-junction thin-film photoelectric converter in which an amorphous silicon photoelectric conversion unit and a crystalline silicon photoelectric conversion unit are stacked, although the wavelength of light which can be converted to electricity by i-type amorphous silicon is no longer than about 800 nm, light of longer wavelength up to about 1,100 nm can be converted to electricity by i-type crystalline silicon. With respect to the amorphous silicon photoelectric conversion layer composed of amorphous silicon having a large light absorption coefficient, in order to achieve light absorption sufficient for photoelectric conversion, even a thickness of 0.3 μm or less is sufficient. In contrast, with respect to the crystalline silicon photoelectric conversion layer composed of crystalline silicon having a small light absorption coefficient, in order to also absorb light of longer wavelength, the thickness is preferably set at about 2 to 3 μm or more. That is, the crystalline silicon photoelectric conversion layer usually needs a thickness that is about ten times the thickness of the amorphous silicon photoelectric conversion layer. Herein, in such a two-junction thin-film photoelectric converter, the amorphous silicon photoelectric conversion unit closer to the light incident side is referred to as a top layer, and the crystalline silicon photoelectric conversion unit disposed behind is referred to as a bottom layer.

The amorphous silicon photoelectric conversion unit has a property referred to as light induced degradation in which the performance is slightly degraded due to light irradiation. The light induced degradation can be more easily suppressed as the thickness of the amorphous silicon photoelectric conversion layer is decreased. However, as the thickness of the amorphous silicon photoelectric conversion layer is decreased, photoelectric current is also decreased. In the multi-junction thin-film photoelectric converter, since the thin-film photoelectric conversion units are joined in series to each other, the current value of the thin-film photoelectric conversion unit having the lowest photoelectric current determines the current value of the multi-junction thin-film photoelectric converter. Therefore, if the thickness of the amorphous silicon photoelectric conversion unit is decreased in order to suppress light induced degradation, the current in the entire photoelectric converter is decreased, resulting in a decrease in conversion efficiency.

In order to overcome the problem described above, a three-junction thin-film photoelectric converter is also used in which another photoelectric conversion unit is interposed between the top layer and the bottom layer of the two-junction thin-film photoelectric converter. Herein, the photoelectric conversion unit disposed between the top layer and the bottom layer is referred to as a middle layer. The band gap of the photoelectric conversion layer in the middle layer must be narrower than that of the top layer and wider than that of the bottom layer. Therefore, as the middle layer, an amorphous silicon photoelectric conversion unit which is an amorphous silicon-based photoelectric conversion unit, a silicon-germanium photoelectric conversion unit including a photoelectric conversion layer composed of an amorphous Si—Ge alloy, or a crystalline silicon photoelectric conversion unit which is a crystalline silicon-based photoelectric conversion unit is generally used. However, when a crystalline silicon photoelectric conversion unit is used as the middle layer, the thickness of the bottom layer considerably increases, resulting in an increase in production cost. Consequently, in the case of the three-junction thin-film photoelectric converter, use of an amorphous silicon-based photoelectric conversion unit as the middle layer is advantageous from the standpoint of production cost.

In order to improve the conversion efficiency of a thin-film photoelectric converter, besides the method described above in which a plurality of thin-film photoelectric conversion units are stacked, a method in which a thin-film photoelectric conversion unit is disposed on a base having surface unevenness may be used. In this method, light scattering increases the optical path length, and as a result, light trapping occurs in the thin-film photoelectric conversion unit to increase photoelectric current. The method is particularly effective for a thin-film photoelectric converter including a crystalline silicon photoelectric conversion unit composed of crystalline silicon having a light absorption coefficient that is lower than that of amorphous silicon.

Furthermore, in order to trap light in the thin-film photoelectric conversion units, a method may be used in which a reflective intermediate layer composed of a conductive material having a lower refractive index than that of the materials constituting the thin-film photoelectric conversion units is disposed between the thin-film photoelectric conversion units. By providing such a reflective intermediate layer, the thin-film photoelectric converter can be designed so that light on the shorter wavelength side is reflected and light on the longer wavelength side is transmitted. Thereby, photoelectric conversion can be performed more effectively in each thin-film photoelectric conversion unit. In the three-junction thin-film photoelectric converter including the middle layer, i.e., the amorphous silicon-based photoelectric conversion unit, light absorption is low in the middle layer, and as a result, it is difficult to extract photoelectric current from the middle layer. By providing a reflective intermediate layer between the middle layer and the bottom layer, it is possible to increase photoelectric current in the middle layer. Thus, in such a three-junction thin-film photoelectric converter, the reflective intermediate layer is particularly effective.

However, the light trapping method described above has problems as described below. When the peak-to-valley height of surface unevenness (hereinafter simply referred to as “unevenness depth”) of the base is increased for the purpose of scattering incident light, grain boundaries tend to be generated from the concave portions. As a result, the film quality of the photoelectric conversion layer is likely to be degraded and internal short circuits are likely to occur, resulting in a decrease in the fill factor (FF). Furthermore, the thin conductivity-type layers have thickness distribution, resulting in a decrease in the open-circuit voltage (Voc). Moreover, at the interface between the thin-film photoelectric conversion units, a reverse junction is present between the conductivity-type layers. When a plurality of photoelectric conversion units are disposed on a base having a large unevenness depth, many energy levels (interface traps) for trapping electrons and holes, i.e., carriers, occur, which may lead to leakage current, thus decreasing the open-circuit voltage (Voc) and the fill factor (FF). This phenomenon appears more remarkably as the thicknesses of the top layer and the middle layer are decreased.

Furthermore, when the reflective intermediate layer is disposed on a base having surface unevenness, the reflective intermediate layer also has surface unevenness corresponding to the surface unevenness of the base. Consequently, light trapping in the reflective intermediate layer becomes not negligible, and light incident on the thin-film photoelectric conversion layer decreases. As a result, the desired improvement in photoelectric current may not be obtained.

Non-patent Document 1 describes multi-junction thin-film photoelectric converters having various structures and discloses an idea of a three-junction thin-film photoelectric converter having a structure in which an amorphous silicon-based photoelectric conversion unit, an amorphous silicon-based photoelectric conversion unit, a reflective intermediate layer, and a crystalline silicon-based photoelectric conversion unit are stacked in that order according to the present invention. Non-patent Document 1 also describes that a photoelectric conversion unit is disposed on a SnO₂ film having surface unevenness. However, Non-patent Document 1 clearly states that a three-junction thin-film photoelectric converter having the structure described above has not been actually fabricated, and consequently, its characteristics have not been evaluated. Therefore, Non-patent Document 1 does not disclose methods for solving the problems, such as the degradation of the film quality due to grain boundaries generated when the crystalline silicon-based photoelectric conversion unit is formed on the base having surface unevenness, and the light trapping in the reflective intermediate layer.

(Non-patent Document 1) D. Fischer et al, Proc. 25^{th} IEEE PVS Conf. (1996), p. 1053

### DISCLOSURE OF INVENTION

### Problems to be Solved by the Invention

Under these circumstances, it is an object of the present invention to provide a thin-film photoelectric converter having high conversion efficiency at low cost by improving the film quality of the crystalline silicon-based photoelectric conversion layer and improving the light trapping effect.

### Means for Solving the Problems

According to the present invention, a thin-film photoelectric converter, which is a three-junction thin-film photoelectric converter, has a structure in which a first amorphous silicon-based photoelectric conversion unit, a second amorphous silicon-based photoelectric conversion unit, a reflective intermediate layer, and a crystalline silicon-based photoelectric conversion unit are stacked in that order from the light incident side, wherein the photoelectric conversion units are disposed on a base having surface unevenness, and the reflective intermediate layer has an unevenness depth that is smaller than that of the base.

Namely, the thin-film photoelectric converter of the present invention is a three-junction thin-film photoelectric converter including a first amorphous silicon-based photoelectric conversion unit, a second amorphous silicon-based photoelectric conversion unit, a reflective intermediate layer, and a crystalline silicon-based photoelectric conversion unit disposed in that order on an uneven principal surface of a transparent base, the transparent base having at least one uneven principal surface, wherein the reflective intermediate layer has an unevenness depth that is smaller than that of the principal surface of the transparent base.

By stacking the crystalline silicon-based photoelectric conversion unit on the reflective intermediate layer having smaller unevenness than that of the transparent base, the light trapping effect can be obtained as a whole because of the surface unevenness of the base, and satisfactory film quality can be achieved because grain boundaries are not generated in the crystalline silicon-based photoelectric conversion unit on the reflective intermediate layer. Consequently, high photoelectric conversion efficiency can be achieved.

Furthermore, a decrease in photoelectric current resulting from light absorption in the reflective intermediate layer because of light trapping in the reflective intermediate layer under the influence of the surface unevenness of the base does not occur. Consequently, high photoelectric conversion efficiency can be achieved.

### ADVANTAGES

According to the present invention, a thin-film photoelectric converter, which is a three-junction thin-film photoelectric converter, has a structure in which a first amorphous silicon-based photoelectric conversion unit, a second amorphous silicon-based photoelectric conversion unit, a reflective intermediate layer, and a crystalline silicon-based photoelectric conversion unit are stacked in that order from the light incident side, wherein the photoelectric conversion units are disposed on a base having surface unevenness, and the reflective intermediate layer has an unevenness depth that is smaller than that of the base. Since the unevenness depth of the reflective intermediate layer is smaller than that of the base, it is possible to inhibit the generation of grain boundaries in the crystalline silicon-based photoelectric conversion layer, and thus it is possible to obtain a crystalline silicon-based photoelectric conversion layer having satisfactory photoelectric conversion properties. Furthermore, since the reflective intermediate layer has such surface unevenness, it is possible to decrease light trapping in the reflective intermediate layer. As a result, incident light on the thin-film photoelectric conversion unit increases, thus increasing photoelectric current. Because of the improvement in the film quality and the improvement in the light trapping effect of the crystalline silicon-based photoelectric conversion layer, it is possible to provide a three-junction thin-film photoelectric converter having high conversion efficiency at low cost. The advantages are obtained not only when the peak-to-peak cycle of the unevenness of the reflective intermediate layer is substantially the same as that of the base but also when the reflective intermediate layer itself has a fine uneven structure in which the peak-to-peak cycle of the unevenness is smaller than that of the base. In particular, the present invention is advantageous from the standpoint of improving the film quality of the crystalline silicon-based photoelectric conversion layer.

### BRIEF DESCRIPTION OF THE DRAWINGS

FIG. 1 is a schematic cross-sectional view which shows a three-junction thin-film photoelectric converter.

FIG. 2 is a schematic cross-sectional view which shows surface unevenness of a reflective intermediate layer in Example 2.

### REFERENCE NUMERALS

12 transparent base
1 transparent plate
2 transparent electrode layer
3a first amorphous silicon photoelectric conversion unit
3b second amorphous silicon photoelectric conversion unit
3c crystalline silicon photoelectric conversion unit
4 reflective intermediate layer
5 back electrode layer

### BEST MODE FOR CARRYING OUT THE INVENTION

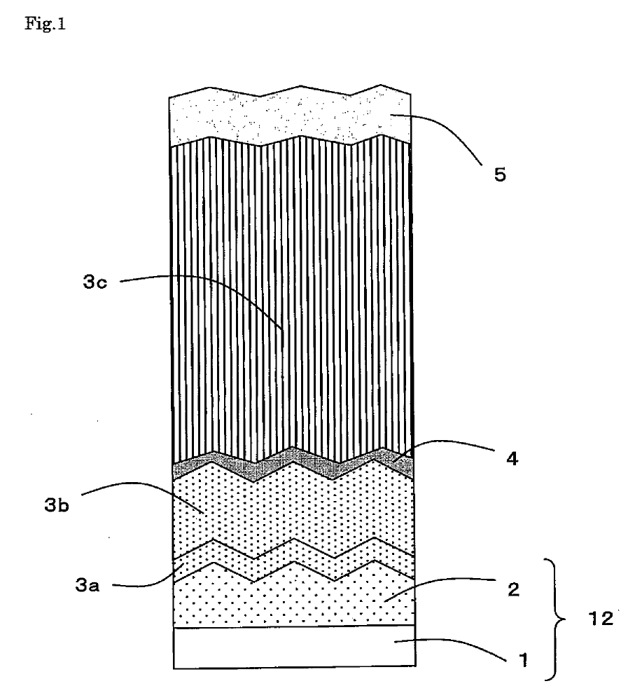

FIG. 1 is a schematic cross-sectional view which shows a three-junction thin-film photoelectric converter according to an embodiment of the present invention. The present invention will be described in detail with reference to FIG. 1. However, it is to be understood that the present invention is not limited thereto.

The individual components of the three-junction thin-film photoelectric converter of the present invention will be described.

A transparent base 12 may be formed by disposing a transparent electrode layer 2, which will be described below, on a principal surface of a transparent plate, for example, composed of a glass plate or a transparent resin film, so that unevenness is provided. Herein, as the glass plate, a soda lime plate glass containing SiO₂, Na₂O, and CaO as main components having smooth principal surfaces can be used. A large-area plate of soda lime plate glass can be readily available inexpensively, and the soda lime plate glass is transparent and highly insulating.

The transparent electrode layer 2 can be composed of a transparent conductive oxide film, such as an ITO film, a SnO₂ film, or a ZnO film. The transparent electrode layer 2 may have a single-layer structure or a multi-layer structure. The transparent electrode layer 2 can be formed using a known vapor-phase deposition process, such as vapor deposition, CVD, or sputtering. The surface of the transparent electrode layer 2 is provided with a textural structure including fine unevenness. The unevenness depth is preferably 0.1 μm to 5.0 μm. Furthermore, the peak-to-peak spacing is preferably 0.1 Mm to 5.0 μm. By providing such a textural structure on the surface of the transparent electrode layer 2, the light trapping effect can be enhanced.

The three-junction thin-film photoelectric converter of the present invention shown in FIG. 1 includes a first amorphous silicon-based photoelectric conversion unit 3a, a second amorphous silicon-based photoelectric conversion unit 3b, a reflective intermediate layer 4, and a crystalline silicon-based photoelectric conversion unit 3c.

The first amorphous silicon-based photoelectric conversion unit 3a and the second amorphous silicon-based photoelectric conversion unit 3b each include an amorphous silicon-based photoelectric conversion layer, and have a structure in which a p-type layer, the amorphous silicon-based photoelectric conversion layer, and an n-type layer are stacked in that order from the transparent electrode layer 2 side. The p-type layer, the amorphous silicon-based photoelectric conversion layer, and the n-type layer each can be formed by plasma CVD. Additionally, the conductivity-type layers of the first amorphous silicon-based photoelectric conversion unit 3a and the conductivity-type layers of the second amorphous silicon-based photoelectric conversion unit 3b may be composed of different materials. Furthermore, the amorphous silicon-based materials, the film quality, the deposition conditions, etc. for the photoelectric conversion layers are not necessarily the same.

On the other hand, the crystalline silicon-based photoelectric conversion unit 3c includes a crystalline silicon-based photoelectric conversion layer, and for example, has a structure in which a p-type layer, the crystalline silicon-based photoelectric conversion layer, and an n-type layer are stacked in that order from the reflective intermediate layer 4 side. The p-type layer, the crystalline silicon-based photoelectric conversion layer, and the n-type layer each can be formed by plasma CVD.

The p-type layers constituting the thin-film photoelectric conversion units 3a, 3b, and 3c can be formed by doping, for example, silicon, silicon carbide, silicon oxide, silicon nitride, or a silicon alloy, such as silicon-germanium, with impurity atoms for determining p-type conductivity, such as boron or aluminum. Furthermore, the amorphous silicon-based photoelectric conversion layer and the crystalline silicon-based photoelectric conversion layer can be formed using an amorphous silicon-based semiconductor material and a crystalline silicon-based semiconductor material, respectively. Examples of such materials include intrinsic silicon semiconductors (e.g., silicon hydride), silicon carbide, and silicon alloys, such as silicon-germanium. Furthermore, a weakly p-type or weakly n-type silicon-based semiconductor material containing a very small amount of an impurity for determining the conductivity type can also be used as long as it has a sufficient photoelectric conversion function. Furthermore, the n-type layers can be formed by doping silicon, silicon carbide, silicon oxide, silicon nitride, or a silicon alloy, such as silicon-germanium, with impurity atoms for determining n-type conductivity, such as phosphorus or nitrogen.

The amorphous silicon-based photoelectric conversion units 3a and 3b and the crystalline silicon-based photoelectric conversion unit 3c, which have the structures described above, have different absorption wavelength ranges. For example, when the photoelectric conversion layers of the amorphous silicon-based photoelectric conversion units 3a and 3b are composed of amorphous silicon and the photoelectric conversion layer of the crystalline silicon photoelectric conversion unit 3c is composed of crystalline silicon, the former is allowed to absorb the light component of about 550 nm most efficiently, and the latter is allowed to absorb the light component of about 900 nm most efficiently.

The thickness of the first amorphous silicon-based photoelectric conversion unit 3a is preferably in a range of 0.01 μm to 0.2 μm, and more preferably in a range of 0.05 μm to 0.1 Ma.

The thickness of the second amorphous silicon-based photoelectric conversion unit 3b is preferably in a range of 0.1 μm to 0.5 μm, and more preferably in a range of 0.15 μm to 0.3 μm.

On the other hand, the thickness of the crystalline silicon-based photoelectric conversion unit 3c is preferably in a range of 0.1 μm to 10 μm, and more preferably in a range of 1 μm to 3 μm.

At the interfaces between the individual photoelectric conversion units, for example, at the interface between the first amorphous silicon-based photoelectric conversion unit 3a and the second amorphous silicon-based photoelectric conversion unit 3b, an n-p reverse junction is present. At the n-p reverse junction interface, current flows by means of recombination of carriers. Preferably, a highly doped, highly defective layer is inserted between the n-type layer and the p-type layer. Specifically, by forming a p-type layer composed of a crystalline silicon-based material with a thickness of 2 nm to 10 nm at the interface between the first amorphous silicon-based photoelectric conversion unit 3a and the second amorphous silicon-based photoelectric conversion unit 3b, recombination of carriers is promoted. As a result, the open-circuit voltage (Voc) and the fill factor (FF) are improved.

As the reflective intermediate layer 4, a transparent conductive oxide layer, such as an ITO film, a SnO₂ film, or a ZnO film, a conductive silicon oxide or silicon nitride layer, or the like is used. The reflective intermediate layer 4 may have a single-layer structure or a multi-layer structure. The reflective intermediate layer 4 can be formed using a known vapor-phase deposition process, such as vapor deposition, CVD, or sputtering.

The thickness of the reflective intermediate layer 4 is preferably in a range of 5 nm to 100 nm, and more preferably in a range of 10 nm to 70 nm. Preferably, the unevenness depth of the resultant reflective intermediate layer 4 is smaller than that of the base, and the peak-to-peak spacing is 0.01 μM to 10 μm.

More preferably, the surface unevenness of the reflective intermediate layer 4 is smaller than that of the base. In such a case, generation of grain boundaries is reduced at the initial stage of formation of the crystalline silicon photoelectric conversion layer, and the film quality is further improved.

Furthermore, in some cases, for the purpose of reducing interface trapping, a high resistivity layer (not shown) having a thickness of 10 nm or less and a conductivity of 1.0×10⁻⁹ S/cm or less is disposed at the interface between the first amorphous silicon photoelectric conversion unit and the second amorphous silicon photoelectric conversion unit, at the interface between the reflective intermediate layer and the crystalline silicon photoelectric conversion unit, or at both interfaces.

The back electrode layer 5 not only functions as an electrode but also functions as a reflective layer which reflects light that has entered the thin-film photoelectric conversion unit 3 from the transparent substrate 1 and reached the back electrode layer 5 to allow light to reenter the thin-film photoelectric conversion unit 3. The back electrode layer 5 can be formed using silver, aluminum, or the like by vapor deposition, sputtering, or the like, for example, at a thickness of about 200 nm to 400 nm.

Additionally, a transparent conductive thin film (not shown) composed of a non-metal material, such as ZnO, may be provided between the back electrode layer 5 and the thin-film photoelectric conversion unit 3, for example, in order to improve adhesion between the both.

### EXAMPLES

The present invention will be described in detail below based on several examples together with comparative examples. However, it is to be understood that the present invention is not limited to the examples described below within the scope not deviating from the object of the invention.

### Example 1

In Example 1, a three-junction thin-film photoelectric converter shown in FIG. 1 was fabricated.

An uneven SnO₂ layer 2 with a thickness of 1 μm, as a transparent electrode layer 2, was formed by CVD on a glass substrate 1 with a thickness of 0.7 mm. Here, the unevenness depth was in a range of 0.1 μm to 0.5 μm, and the peak-to-peak spacing was in a range of 0.1 μm to 0.5 μm. On the transparent electrode layer 2, silane, hydrogen, methane, and diborane as reaction gases were introduced to form a p-type layer with a thickness of 15 nm, silane as a reaction gas was then introduced to form an amorphous silicon photoelectric conversion layer with a thickness of 70 nm, and lastly, silane, hydrogen, and phosphine as reaction gases were introduced to form an n-type layer with a thickness of 10 nm. Thereby, a first amorphous silicon photoelectric conversion unit 3a was formed. Subsequently, in order to promote the tunneling effect of carriers at the np reverse junction interface, silane, hydrogen, and diborane as reaction gases were introduced to form a crystalline silicon p-type layer with a thickness of 5 nm. Next, silane, hydrogen, methane, and diborane were introduced to form a p-type layer with a thickness of 5 nm, silane as a reaction gas was then introduced to form an amorphous silicon photoelectric conversion layer with a thickness of 250 nm, and lastly, silane, hydrogen, and phosphine as reaction gases were introduced to form an n-type layer with a thickness of 10 nm. Thereby, a second amorphous silicon photoelectric conversion unit 3b was formed. After the second amorphous silicon photoelectric conversion unit 3b was formed, silane, hydrogen, phosphine, and carbon dioxide as reaction gases were introduced to form a reflective intermediate layer 4 composed of a silicon oxide layer with a thickness of 40 nm. In the reflective intermediate layer, the unevenness depth was in a range of 0.05 μm to 0.4 μm, and the peak-to-peak spacing was in a range of 0.1 μm to 1.0 μm. After the reflective intermediate layer 4 was formed, silane, hydrogen, and diborane as reaction gases were introduced to form a p-type layer with a thickness of 10 nm, hydrogen and silane as reaction gases were then introduced to form a crystalline silicon photoelectric conversion layer with a thickness of 1.7 μm, and lastly, silane, hydrogen, and phosphine as reaction gases were introduced to form an n-type layer with a thickness of 15 nm. Thereby, a crystalline silicon photoelectric conversion unit 3c was formed. The amorphous silicon photoelectric conversion units 3a and 3b, the crystalline silicon photoelectric conversion unit 3c, and the reflective intermediate layer 4 were each formed by plasma CVD.

Subsequently, in order to improve adhesion with a back electrode 5, a ZnO layer with a thickness of 90 nm was formed by sputtering, and then an Ag layer 5 as the back electrode 5 was formed by sputtering. The three-junction thin-film photoelectric converter (light reception area: 1 cm²) thus obtained was irradiated with light of AM 1.5 at a light intensity of 100 mW/cm², and the output characteristics were measured. As shown in Table 1, Example 1, the open-circuit voltage (Voc) was 2.29 V, the short-circuit current density (Jsc) was 7.28 mA/cm², the fill factor (F.F.) was 78.1%, and the conversion efficiency was 13.0%.

The measurement results of the output characteristics of the three-junction thin-film photoelectric converters in the individual examples and comparative examples are shown in Table 1.

TABLE 1

| | | | | Conversion |
|---|---|---|---|---|
| | Voc | Jsc | FF | efficiency |
| | [V] | [mA/cm²] | [%] | [%] |
| Example 1 | 2.29 | 7.28 | 78.1 | 13.0 |
| Example 2 | 2.35 | 7.35 | 78.3 | 13.5 |
| Comparative | 2.24 | 7.25 | 75.3 | 12.2 |
| Example 1 | | | | |
| Comparative | 2.27 | 5.67 | 17.3 | 9.9 |
| Example 2 | | | | |
| Comparative | 2.21 | 6.82 | 14.6 | 11.2 |
| Example 3 | | | | |

### Example 2

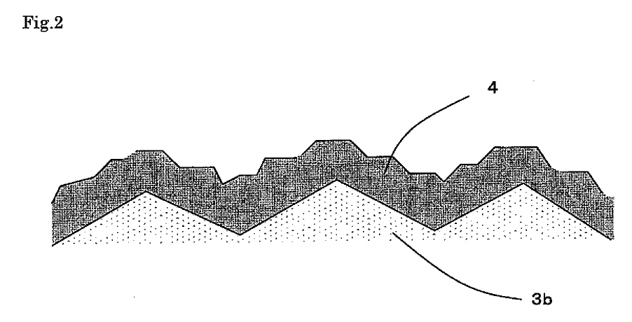

In the same structure as that in Example 1, hydrogen, phosphine, and carbon dioxide were introduced to form a reflective intermediate layer 4 composed of a silicon oxide layer with a thickness of 40 nm. In Example 2, the reflective intermediate layer 4 had a structure in which one surface had unevenness substantially following the unevenness of the base having an unevenness depth of 0.1 μm to 0.4 μm and a peak-to-peak spacing of 0.1 μm to 0.5 μm and the other surface had small unevenness having a peak size of 0.01 μm to 0.02 μm as shown in the schematic diagram of FIG. 2. In this case, with respect to the output characteristics of the three-junction thin-film photoelectric converter, as shown in Table 1, Example 2, the open-circuit voltage (Voc) was 2.35 V, the short-circuit current density (Jsc) was 7.35 mA/cm², the fill factor (FF) was 78.3%, and the conversion efficiency was 13.5%.

### Comparative Example 1

In the same structure as that in Example 1, hydrogen, phosphine, and carbon dioxide were introduced to form a reflective intermediate layer 4 composed of a silicon oxide layer with a thickness of 40 nm. In Comparative Example 1, the reflective intermediate layer 4 had an unevenness depth of 0.1 μm to 0.5 μm and a peak-to-peak spacing of 0.2 μm to 0.5 μm. In this case, with respect to the output characteristics of the three-junction thin-film photoelectric converter, as shown in Table 1, Comparative Example 1, the open-circuit voltage (Voc) was 2.24 V, the short-circuit current density (Jsc) was 7.25 mA/cm², the fill factor (FF) was 75.3%, and the conversion efficiency was 12.2%. As a result, the conversion efficiency is lower than that of Example 1 or 2.

### Comparative Example 2

A three-junction thin-film photoelectric converter was fabricated as in Example 1 except that a reflective intermediate layer 4 was not formed. In this case, with respect to the output characteristics of the three-junction thin-film photoelectric converter, as shown in Table 1, Comparative Example 2, the open-circuit voltage (Voc) was 2.27 V, the short-circuit current density (Jsc) was 5.67 mA/cm², the fill factor (FF) was 77.3%, and the conversion efficiency was 9.9%. In Comparative Example 2, since the reflective intermediate layer 4 is not present, the light trapping effect is low in the top layer and the middle layer, resulting in a decrease in photoelectric current. As a result, the conversion efficiency is lower than that of Example 1 or 2.

### Comparative Example 3

A three-junction thin-film photoelectric converter was fabricated as in Example 1 except that a reflective intermediate layer 4 was not formed, the thickness of the amorphous silicon photoelectric conversion layer of the top layer was set at 90 nm, and the thickness of the amorphous silicon photoelectric conversion layer of the middle layer was set at 300 nm. In this case, with respect to the output characteristics of the three-junction thin-film photoelectric converter, as shown in Table 1, Comparative Example 3, the open-circuit voltage (Voc) was 2.21 V, the short-circuit current density (Jsc) was 6.82 mA/cm², the fill factor (FF) was 74.6%, and the conversion efficiency was 11.2%. In Comparative Example 3, since the thickness of the photoelectric conversion layer of each of the top layer and the middle layer is increased compared to Comparative Example 2, a decrease in photoelectric current due to the absence of the reflective intermediate layer 4 is suppressed. However, since the thickness of the amorphous silicon photoelectric conversion layer is increased, the open-circuit voltage (Voc) and the fill factor (FF) are decreased. As a result, the conversion efficiency is lower than that of Example 1 or 2.

1. A three-junction thin-film photoelectric converter comprising a first amorphous silicon-based photoelectric conversion unit, a second amorphous silicon-based photoelectric conversion unit, a reflective intermediate layer, and a crystalline silicon-based photoelectric conversion unit disposed in that order on an uneven principal surface of a transparent base, the transparent base having at least one uneven principal surface, wherein the reflective intermediate layer has an unevenness depth that is smaller than that of the principal surface of the transparent base.
